(19) United States
(12) Patent Application Publication
(10) Pub. No.: US 2010/0080254 A1
(43) Pub. Date: Apr. 1, 2010

(54) TEMPERATURE TUNING OF OPTICAL DISTORTIONS

(76) Inventors: Paul B. Lundquist, Vail, AZ (US); Stephen McCahon, Tucson, AZ (US); Jiamin (Jim) Zhang, Tucson, AZ (US)

Correspondence Address: Duft Bornsen & Fishman, LLP, P.O. Box 1510, Boulder, CO, 80306-1510, US

(21) Appl. No.: 12/562,394

(22) Filed: Sep. 18, 2009

Related U.S. Application Data
(60) Provisional application No. 61/100,508, filed on Sep. 26, 2008.

(51) Int. Cl. H01S 3/042; H01S 5/00

(52) U.S. Cl. 372/35; 372/43.01

(57) ABSTRACT

The systems and methods herein provide for tuning an optical characteristic of a gain medium for a laser system. For example, a system may include a thermal tuner that dynamically controls the temperature of the gain medium to compensate for thermal mechanical distortions of the gain medium caused by laser energy in the gain medium. In doing so, the tuner may dynamically adjust a coolant temperature and/or a coolant flow rate proximate to the gain medium. Accordingly, heat is dynamically removed from the gain medium so as to adjust for optical distortions in the gain medium. Such a dynamic heat removal may provide a laser system designer with the ability to generate laser energy with controllable predetermined optical wavefronts (e.g., a flat optical wavefront).

### CROSS REFERENCE TO RELATED APPLICATIONS

This patent application claims priority from and is therefore entitled to the earlier filing date of U.S. Provisional Patent Application No. 61/100,508 (filed Sep. 26, 2008 and entitled “Temperature Tuning Disk Distortions”), the entire contents of which are hereby incorporated by reference.

### BACKGROUND

Solid state lasers may be diode pumped, flashlamp pumped, or pumped by another laser source. Regardless of the pumping technique, solid state lasers operating at relatively high average power are often susceptible to thermal distortions resulting from the optical pumping process. The sources of heat in typical optically pumped laser materials can be attributed to several sources, such as non radiative decay from excited levels to the ground state, non-radiative decay from the terminal laser level, as well as reabsorption of spontaneous emission. While the details of the heating contributions from each effect vary from material to material and the specifics of the pumping scheme and gain geometry, the resulting internal heating of the lasing material generally leads to the formation of thermal gradients.

Thermal gradients lead to gradients in the index of refraction of the laser material and cause significant phase distortion of a laser beam. In addition, when thermal gradients are severe, significant stresses and strains are induced in the laser material, which result in strain induced distortion of surfaces traversed by the laser beam, further degrading the output beam quality. When optical surfaces are subjected to sufficiently high stress levels, thermally induced fracture of the laser material can occur. Such material fractures may limit power scaling of solid state lasers.

Compensating the thermal distortion has become increasingly problematic as the power is scaled up. For example, an induced thermal optical distortion may be relatively significant and have variable attributes that preclude full compensation by a single external focusing element. Alternative wavefront compensation techniques previously included adaptive optical mirrors and phase conjugation that have produced limited results as they are generally only effective in cases where the aberrations are residual or relatively mild. Furthermore, most adaptive optical solutions employed to date involve complex designs which are generally expensive to implement.

### SUMMARY

The systems and methods shown and described herein provide for tuning an optical characteristic of laser energy from a laser system. For example, a system may include a thermal tuner that dynamically controls the temperature of the gain medium to compensate for thermal mechanical distortions of the gain medium and/or the surrounding mount structure caused by laser energy in the gain medium. In other words, heat is dynamically removed from the gain medium so as to adjust for optical distortions of the gain medium. Such a dynamic heat removal may provide a laser system designer with the ability to generate laser energy with controllable optical wavefronts (e.g., a flat optical wavefront).

In one embodiment, a laser system includes a pump laser source operable to generate optical energy, a gain medium (e.g., Ytterbium doped) operable to generate laser energy from the optical energy. The gain medium includes a thermally conductive material and a tuner in thermal communication with the thermally conductive material (e.g., silicon carbide). The tuner is operable to controllably adjust a temperature of the gain medium via the thermally conductive material to optically distort the gain medium and change an optical wavefront of the laser energy.

The thermally conductive material may have a thermal conductivity of at least 3 W/(cm·K). The tuner may be operable to adjust a temperature of a coolant (e.g., water) flowing proximate to the thermally conductive material to optically distort the gain medium.

The tuner may include first and second ports operable to flow the coolant proximate to the thermally conductive material. Alternatively or additionally, the tuner may be operable to adjust a flow rate of a coolant flowing proximate to the thermally conductive material to optically distort the gain medium. For example the tuner may be operable to flow the coolant through the first and second ports at first and second flow rates and wherein the first flow rate is different than the second flow rate.

The laser system may also include a mount configured from copper tungstate and configured to retain the gain medium. The laser system may also include a feedback system operable to detect an optical characteristic of the optical wavefront of the laser energy and direct the tuner to change a temperature, a flow rate, or a combination thereof, of a coolant flowing proximate to the gain medium to counter an optical distortion of the gain medium and change the optical characteristic of the optical wavefront. In this regard, the thermally conductive material may be configured as two plates disposed about a gain material, wherein each plate has a flow port operable to circulate the coolant proximate to the gain medium. The optical characteristic of the optical wavefront of the laser energy may include a beamspot size, a wavefront radial measurement, or a combination thereof to determine a focus of the laser energy, a phase distortion of the laser energy, or a combination thereof. The determined focus, phase distortion, or combination may then be used to generate a control signal operable to direct the tuner.

In another embodiment, a method of controlling an optical wavefront of laser energy includes pumping a gain medium to generate laser energy and controllably adjusting a temperature of the gain medium to change an optical wavefront of the laser energy exiting the gain medium. Controllably adjusting a temperature of the gain medium may include flowing a coolant proximate to the gain medium at a first flow rate to optically distort the gain medium and change the optical wavefront of the laser energy. For example, the method may include flowing the coolant through a second coolant port at a second flow rate proximate to the gain medium to further optically distort the gain medium. The gain medium may be a Yb:YAG gain medium configured between first and second transmissive mediums (e.g., silicon carbide) each having a thermal conductivity of at least 3 W/(cm·K). Alternatively, the gain medium may be configured between a reflective cooling medium and a transmissive cooling medium such that the output laser energy reflects from the reflective cooling medium through the gain medium and the transmissive cooling medium.

Controllably adjusting a temperature of the gain medium may include changing a flow rate of a coolant flowing proximate to a thermally conductive transmissive plate that is disposed proximate to the gain medium. Alternatively or additionally, controllably adjusting a temperature of the gain medium may include changing a temperature of a coolant flowing proximate to a thermally conductive transmissive plate that is disposed proximate to the gain medium.

The method may further include detecting an optical characteristic of the laser energy and generating a control signal based on the detected optical characteristic to controllably adjust the temperature of the gain medium. For example, the method may include determining a focus of the laser energy, a phase distortion of the laser energy, or a combination thereof based on the detected optical characteristic to generate a control signal operable to direct the tuner.

### BRIEF DESCRIPTION OF THE DRAWINGS

FIG. 1 is a block diagram of an exemplary laser system.

FIGS. 2-4 illustrate thermal mechanical distortions of a gain medium.

FIG. 5 illustrates exemplary compensation calculations of thermal mechanical distortion in a gain medium.

FIG. 6 illustrates an exemplary gain medium with thermally conductive material layers.

FIG. 7 illustrates the gain medium of FIG. 6 with tunable cooling.

FIG. 8 is a block diagram of an exemplary configuration of the gain medium.

FIG. 9 illustrates an exemplary laser gain medium configuration with a radially cooled gain medium having multiple cooling ports configured in a thermally conductive mount.

FIGS. 10 and 11 illustrate exemplary optical path lengths based on thermal tuning of a gain medium.

FIG. 12 is a graph of thermal mechanical distortion versus pump power of a laser resulting from various coolant flow rates.

FIG. 13 is a flowchart of a process for dynamically compensating optical distortion in a laser system.

### DETAILED DESCRIPTION OF THE DRAWINGS

While the invention is susceptible to various modifications and alternative forms, specific embodiments thereof have been shown by way of example in the drawings and are herein described in detail. It should be understood, however, that it is not intended to limit the invention to the particular form disclosed, but rather, the invention is to cover all modifications, equivalents, and alternatives falling within the scope and spirit of the invention as defined by the claims.

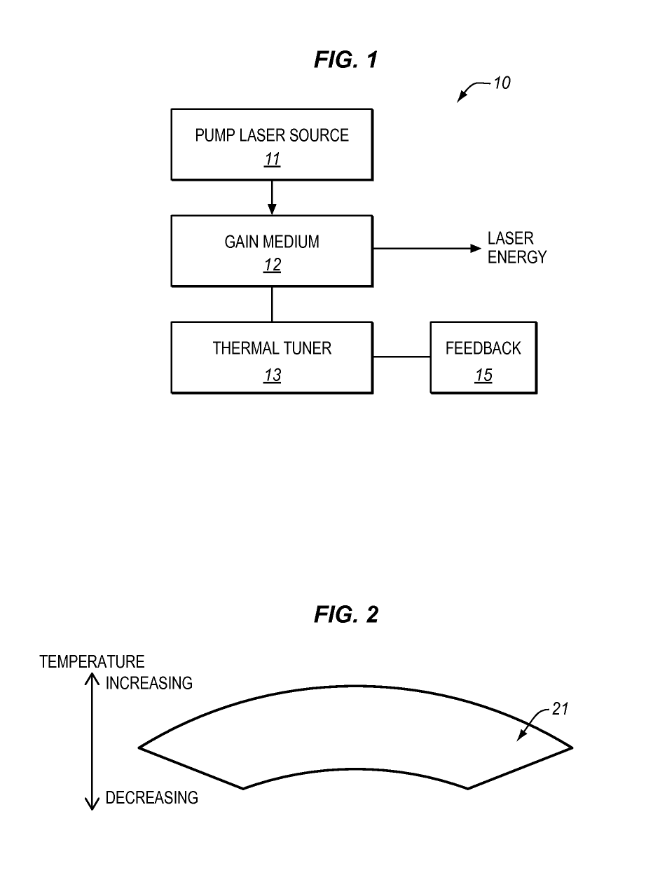

With respect to the drawings, FIG. 1 illustrates a block diagram of an exemplary laser system 10. In this embodiment, the laser system is configured with a pump laser source 11 that is operable to generate optical energy for propagation to a gain medium 12 which in turn radiates laser energy from the laser system 10. The gain medium 12 may be configured from solid state materials (e.g., a crystalline solid host material) that are doped with ions to provide required energy states for high powered laser applications. An ytterbium doped yttrium-aluminium-garnet crystal (Yb:YAG) is one such active laser medium that provides relatively high power laser energy at a wavelength of around 1030 nm. The Yb:YAG gain medium has a relatively broad absorption band of around 940 nm. The dopant levels in such an embodiment range between 0.2-30% of replaced yttrium atoms. Yb:YAG lasers have several advantages that include low fractional heating, high slope efficiency, and little or no excited state absorption or up conversion. Other advantages include the ability to configure the high optical energy into ultra short pulses. Moreover, Yb:YAG lasers have high mechanical strength and high thermal conductivity.

Even with such mechanical strength and thermal conductivity, Yb:YAG gain mediums are still subject to optical distortions when used in high power laser applications. To compensate for these thermal distortions, the laser system 10 is also configured with a tuner 13 that is in thermal communication with the gain medium 12 to controllably change one or more optical characteristics of the gain medium (e.g., certain focusing effects caused by thermal energy within the gain medium). The tuner 13 may change the optical characteristics according to the spatial distortions in the laser energy. For example, as the output power of the laser energy from the gain medium 12 increases, heat generates within the gain medium to distort the optical properties of the gain medium (e.g., via thermal lensing). The tuner 13 may, therefore, compensate or “cool” the gain medium 12 to adjust the optical distortions of the laser energy.

The tuner 13 is not intended to be limited to a static determination of cooling temperatures and/or their flow rates. Rather, a feedback system 15 may be configured with the laser system so as to dynamically tune the cooling/heating of the gain medium 12 and compensate for the thermal mechanical optical distortions. For example, the laser energy exiting the laser system 10 may be detected by the feedback system 15 to determine distortion in the beam (e.g., a distorted optical wavefront). Based on that distortion, the tuner 13 may alter the cooling/heating effects on the gain medium 12 to compensate for the distortion. In this regard, the feedback system 15 may include an optical sensor that is operable to detect the optical distortion and generate a control signal operable to tune the tuner 13 based on the optical distortion.

Although the gain medium 12 is described as a Yb:YAG gain medium, the invention is not intended to be so limited. Other materials may be used as a gain medium that are similarly susceptible to thermal distortion. For example, neodymium is one example of a dopant used in solid state laser crystals, including yttrium orthovanadate (Nd:YVO4), yttrium lithium fluoride (Nd:YLF) and yttrium aluminium garnet (Nd:YAG). Each of these lasers can produce high powers in the infrared spectrum at 1064 nm. Holmium, thulium, and erbium are other dopants that may be used in solid state lasers. Examples of other ytterbium doped crystals include Yb:YAG, Yb:KGW, Yb:KYW, Yb:SYS, Yb:BOYS, Yb:CaF2, each of which typically operates around 1020-1050 nm. These lasers are generally efficient and often high powered due to a particular quantum effect.

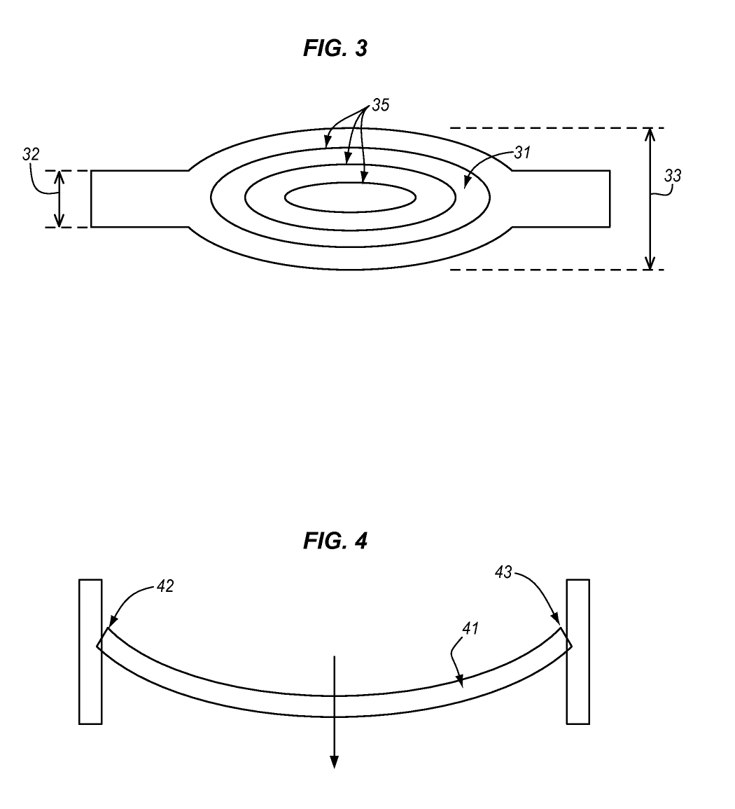

FIGS. 2-4 illustrate thermal mechanical distortions of a gain medium, such as the gain medium 12 of FIG. 1. For example, FIG. 2 illustrates longitudinal heat flow in a disk shaped gain medium wherein one surface is hotter than another such that the gain medium 21 experiences greater radial thermal expansion that leads to a curvature of the gain medium. Such may occur due to heating on one side via the laser energy and/or the cooling of the gain medium 21 on the opposite side of the gain medium. In any case, the curvature alters the focusing aspects of the gain medium 21 and distorts the laser energy output from the gain medium. FIG. 3 illustrates a “bulging” of the gain medium 31 as laser energy generates heat to expand the gain medium and alter the optical characteristics of the gain medium. For example, reference points 32 and 33 illustrate bulging of the gain medium 31 from an original thickness 32 to a heat expanded thickness 33. FIG. 4 illustrates a gain medium 41 that is fixed between two points 42 and 43 (e.g., optical elements such as mirrors and/or mounts). As the laser energy generates heat in the gain medium 41, the gain medium expands and bends either concave or convex due to the fixed nature of the medium between the two points. This bending of the gain medium changes the optical characteristics of the gain medium 41. In addition to these thermal mechanical effects, the laser energy may generate heat within the gain medium 41 and create a temperature dependent index of refraction (e.g., a thermal lens) change, causing an optical distortion in the gain medium 41.

Because the tuner 13 is capable of adjusting to the output power the laser energy, the tuner 13 may be configured with a variety of laser systems. For example, the tuner 13 may be configured with a variety of laser configurations that statically generate laser energy at a single output power level. That is, the tuner 13 may be adapted to correct any laser systems optical distortions by tuning according to that laser'output optical characteristics. However, the tuner may be used to operate in a variety of manners that include, for example, distortion of the optical energy based on a design choice. For example, a lens may be desired for a particular application that, while providing some expected feature, imparts some optical distortion on the laser energy. The tuner may be used to compensate for the distortion by imparting other distortion of the optical energy via the thermal mechanical distortion of the gain medium.

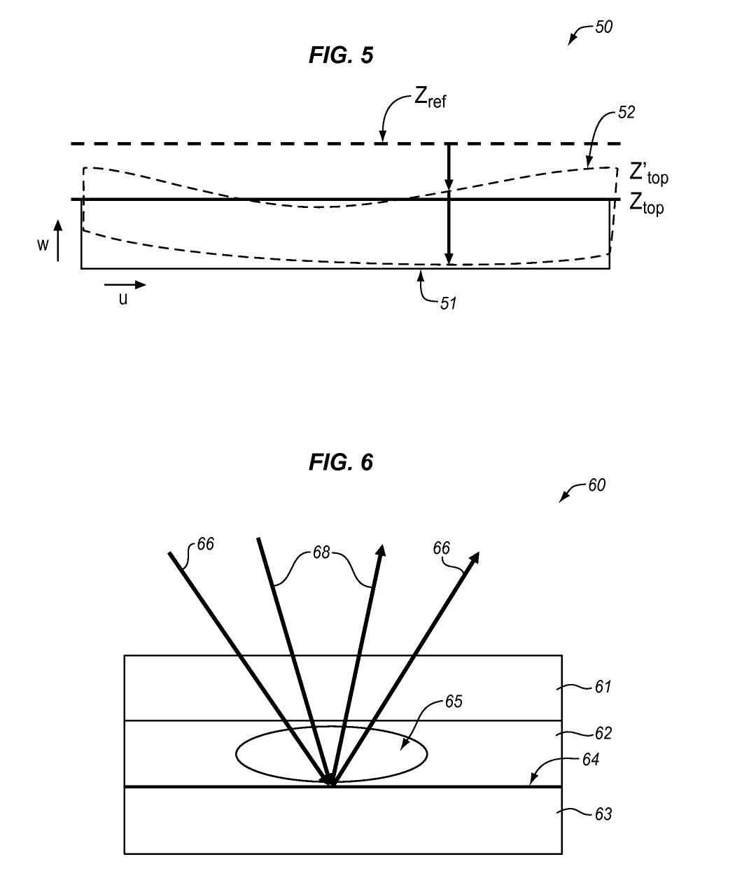

FIG. 5 illustrates exemplary compensation calculations of optical path length caused by the thermal mechanical distortion in a thin disk gain medium 50 where the lower surface of the disk is a reflective surface. The optical path length is the integrated product of the geometric length of the path that light follows and the index of refraction of the gain medium 50 through which the light propagates. A difference in optical path length between two paths is generally referred to as the optical path difference. The optical path length determines the phase of the light and controls the refraction of the light as it propagates. Generally, it is desirable to maintain a relatively flat wavefront for the optical energy such that the phase, refraction of the light may be controlled without the use of additional optical elements, such as lenses.

In this embodiment, the gain medium 50 is illustrated in two shapes. The shape 51 of the gain medium 50 illustrates the original shape prior to optical energy generating heat within the gain medium 50. The shape 52 of the gain medium 50 illustrates one exemplary thermal mechanical distortion of the gain medium 50 once the optical energy generates heat therein. The optical path length may be computed by taking into consideration the shape change in the gain medium 50 from the original shape 51 to the thermally distorted shape 52. To do so, an arbitrary reference point Z_{ref} may be chosen to distinguish the differences between the reference point and the “top” Zₜₒₚ of the original shape 51 and the “top” Z′ₜₒₚ of the distorted shape 52.

With this in mind, the distortion w (e.g., in the vertical direction) and the distortion u (e.g., in the horizontal direction) may be used to calculate the optical path length L. For example, the distortions u and w are a function of the radial position and the longitudinal position z within the undistorted gain medium z. In this regard, the longitudinal position of a volumetric differential element within a gain medium z′ may be computed as

z′=z+w(r,z), (Eq. 1)

where z is the original longitudinal position within the gain medium and r is the original radial position within the undistorted gain medium. The change in radial positions within the distorted gain medium, r′, may be computed as

r′=r+u(r,z), (Eq. 2)

where u is also a function of r and z. The index of refraction n may be computed as

$$n = {n}_{0} + \frac{\partial n}{\partial T} ( T - {T}_{0} ) , \qquad ( Eq . 3 )$$

where n₀ is the index of refraction for the gain material when it is at a temperature T₀. T is the spatially dependent temperature field after heating by the lasing energy. The optical path length L from the reference position Z_{ref} to the bottom of the disk may be computed as:

$$L = {\int }_{{z}_{bottom}^{′}}^{{z}_{top}^{′}} n ( {z}^{′} ) d {z}^{′} + ( {z}_{ref}^{′} - {z}_{top}^{′} ) , \qquad ( Eq . 4 )$$

where n is a function of z′. However, it is generally more convenient to perform the calculation with respect to the undistorted geometry using the distortion mappings u and w.

$$L = {\int }_{{z}_{bottom}}^{{z}_{top}} n ( z ) ( 1 + \frac{\partial w}{\partial z} - \frac{\partial w}{\partial r} \frac{\partial u}{\partial z} ) d z + ( {z}_{ref} - {z}_{top} - {w}_{top} ) , \qquad ( Eq . 5 )$$

In equation 5, wₜₒₚ is the vertical deformation at the top surface of the disk. The temperature dependent index of refraction is included by inserting Equation 3 into Equation 4, resulting in Equation 6, below.

$$L = {\int }_{{Z}_{bottom}}^{{Z}_{top}} ( {n}_{0} + \frac{\partial n}{\partial T} ( T - {T}_{0} ) ) ( 1 + \frac{\partial w}{\partial z} + \frac{\partial w}{\partial r} \frac{\partial u}{\partial z} ) d z + ( {z}_{ref} - {z}_{top} - {w}_{top} ) , . \qquad ( Eq . 6 )$$

For a specific thin disk gain medium with a specified mount and cooling geometries, a finite element modeling (FEM) analysis can be performed using standard commercially available modeling tools. The FEM analysis may yield the temperature field and deformation fields u and w. Equation 6 may then be used to calculate the single pass optical path length to the mirrored surface on the back side of the thin disk gain medium. The total optical path length is 2·L.

By designing the cooling and mounting geometry so that cooling is provided at two or more different locations and controlled for at least one of those locations, parametric control of the thermal distortions can be achieved. More specifically, for an appropriately designed mount and cooling system, dynamic cooling may be performed on the gain medium such that the optical path length can be tuned as desired and thereby configure a flat wavefront for the optical energy according the heating of the gain medium.

FIG. 6 illustrates an exemplary gain medium 60 having a laser gain material 62 disposed between thermally conductive material layers 61 and 63. The gain medium 60 also has a reflective layer 64 disposed between the gain material 62 and the thermally conductive layer 63. The gain medium 60 is configured to receive “pump” optical energy 66 which is used to amplify the optical energy 68 from a laser source, thereby producing laser energy. In this process, the pump optical energy 68 generates heat within the gain material 62 (e.g., in the region 65). For example, due to the quantum defect, laser pump energy that is not converted into laser gain or fluorescence is generally converted into heat within the gain material 62. This heating of the gain material 62, as mentioned, tends to alter the shape of the gain material 62 and thus alter the optical path length of the laser energy. To compensate for these thermal mechanical distortions, the gain medium 60 includes the thermally conductive layers 61 and 63 to extract heat from the gain material 62. These thermally conductive layers 61 and 63 may be in thermal communication with the tuner 13 of FIG. 1. For example, the tuner 13 may be used to control the flow and/or the temperature of a coolant, such as water (although other coolants may be used), proximate to the thermally conductive layers 61 and 63 such that the heat that is generated within the gain material 62 may be removed from the gain medium 60 and control the thermal mechanical distortion of the gain medium.

In one embodiment, the tuner 13 may control the coolant flow about the thermally conductive layers 61 and 63 independently. For example, the heating of the gain material 62 by the laser energy may be nonuniform thereby producing nonuniform thermal mechanical distortions in the gain material 62. Alternatively, the mechanical mount for the gain medium may be intentionally asymmetric to force the mechanical distortions to occur in a predictable manner. In this regard, the tuner 13 may control the coolant flow proximate to the thermally conductive layer 61 at a rate that differs from the coolant flow proximate to the thermally conductive layer 63 to independently adjust the heat removal from the gain material 62.

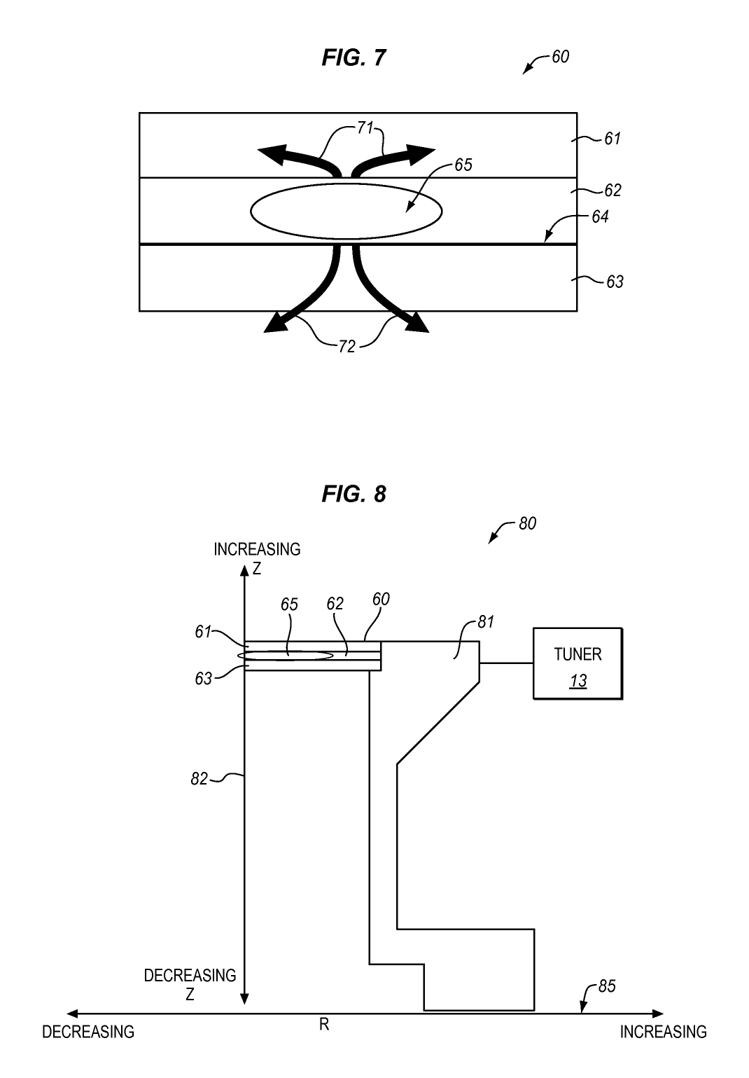

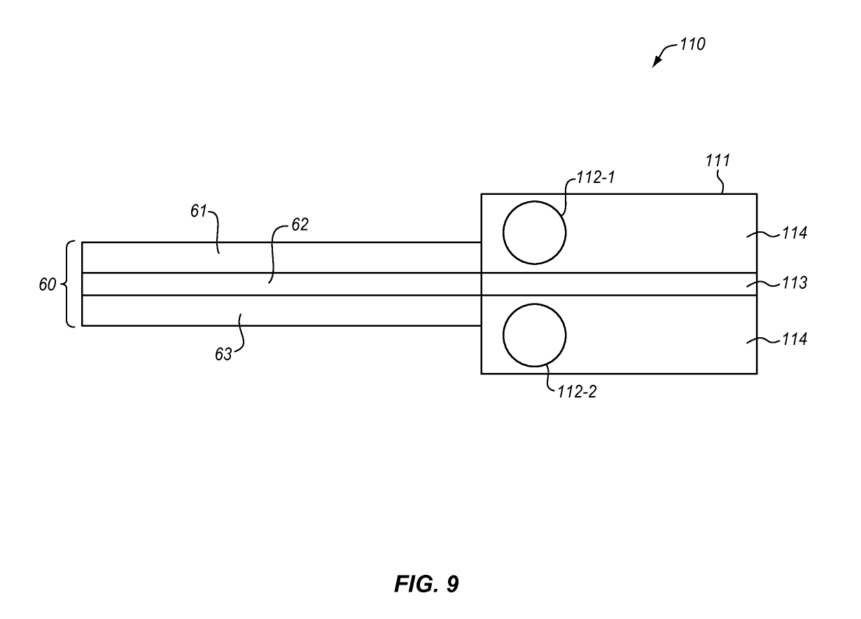

Alternatively, the thermal design may be asymmetric with respect to the top and bottom of the gain medium such that the temperature difference between the top and bottom depends on the cooling that is provided. For example, FIG. 7 illustrates the gain medium 60 with the heat being removed from the region 65 within the gain material 62 in differing manners. To do so, the tuner 13 may control the flow rate and/or temperature of the coolant proximate to the thermally conductive layer 61 such that the heat is removed from the region 65 in the direction 71 while the flow rate and/or the temperature of the coolant proximate to the thermally conductive layer 63 flows at a different rate to remove the heat from the region 65 in the direction 72. Such independent adjustment of at least one thermal flow route has the advantage of controlling nonuniform heating of the gain medium 60 such that a relatively flat optical energy wavefront may be produced. It is important to note that the controlled thermal flow may actually induce mechanical stresses in either the gain medium or mount that can counter other distortion processes (e.g., those shown in FIGS. 2-4).

The invention, however, is not intended to be limited to any particular type of flow rate, temperature, or gain medium structure. For example, the flow rates of the coolant proximate to the thermally conductive layers 61 and 63 may be the same or different depending on the specific application of the laser system. That is, laser system designers may desire output laser energy that has a curved yet predictable wavefront. Alternatively, the heating caused by the laser energy may cause uniform thermal mechanical distortions of the gain material 62 such that the thermally conductive layers 61 and 63 require similar coolant flow rates and/or temperatures to maintain a relatively flat optical energy wavefront. Other configurations may even have a thermally conductive layer removed from the gain medium 60 (e.g., the thermally conductive layer 63) to provide a certain optical effect that is controllable by the tuner 13 via the remaining thermally conductive layer.

Examples of materials that may be used for the thermally conductive layers 61 and 63 include silicon carbide and diamond. The advantages of such materials include a relatively high thermal conductivity of about 4W/(cm·K) while remaining exceptionally transmissive. Thus, the thermally conductive layers 61 and 63 generally do not interfere with the wavefront of the laser energy exiting the gain medium.

FIG. 8 is a block diagram of an exemplary configuration 80 of the gain medium 60 also illustrating the change in thermal mechanical distortion of the gain medium 60 and its correspondence to the radius of curvature of an optical wavefront resulting from the thermal mechanical distortion. For example, as the gain material 62 heats from the pump radiation within the region 65 of the gain material 62, the longitudinal position of the gain material 62 shifts (e.g., either increasingly so or decreasingly so). This shift causes a corresponding change in the radius of curvature of the optical wavefront.

The gain medium 60 is configured with a generally thermally conductive mount 81 that is used remove heat from or “cool” the gain material 62 (e.g., the region 65). In this regard, the tuner 13 may be in thermal communication with the mount 81 so as to control the flow rate of a coolant proximate to the gain medium 60. More particularly, the tuner may control the flow rate of the coolant through the mount 81 proximate to the thermally conductive layers 61 and 63. An example of such is shown and described in greater detail in FIG. 9. In one embodiment, the thermally conductive mount 81 is configured of copper tungstate (CuW) due to its relatively high thermal conductivity of about 1.8 W/(cm·C) and its rigidity. However, other materials may also be suitable.

FIG. 9 illustrates an exemplary laser gain medium configuration 110 with a radially cooled gain medium 60 having multiple cooling ports configured in a thermally conductive mount 111. In this embodiment, the laser gain medium configuration 110 is illustrated in a side view such that the materials thereof have depth (i.e., the materials extend into the page). As mentioned above, heating at the gain material 62 by pump optical energy may cause thermal mechanical distortions in the gain medium 60 resulting in a potentially unpredictable optical path length of the laser energy. A thermally conductive mount 111 is illustrated herein as being configured with two coolant flow ports 112 within the thermally conductive materials 114 of the mount. The thermally conductive materials 114 may have a layer of insulation 113 disposed between the materials that is affixed to the gain material 62 of the gain medium 60. The thermally conductive materials 114 are in thermal communication with the thermally conductive material 61 and 63 of the gain medium 60. The tuner 13 as described above is operable to flow coolant (e.g., chilled water, liquid nitrogen, etc.) through the two coolant flow ports 112. Due to the close proximity of the coolant ports 112, coolant flowing through the ports 112 is operable to cool the thermally conductive layers 61 and 63 and thereby remove heat from the gain material 62.

The insulation 113 that separates the thermally conductive layers 114 from one another may also generally prevent the direct cooling of the gain material 62. This “passive cooling” may provide the laser gain medium configuration 110 with more thermal mechanical distortion control. For example, the thermally conductive layers 61 and 63 may rigidly support the gain material 62. If the coolant were to flow proximate to the gain material 62, the gain material 62 may experience nonuniform heat removal such that thermal mechanical distortions still occur. The laser gain medium configuration 110 obviates such nonuniform heat removal by providing a suitable form of cooling of the gain material 62 via the thermally conductive layers 61 and 63. For example, should nonuniform heat removal occur, the tuner 13 may provide a differential flow rate and/or temperature between the ports 112 to counter the nonuniform heat removal. In other words, the tuner 113 may flow the coolant through the flow port 112-1 at one rate and/or temperature and flow the coolant through the flow port 112-2 at a second different rate and/or temperature. In this regard, thermal mechanical distortions in one direction of the gain medium 60 caused by a particular heat removal in the thermally conductive layer 61 may be “balanced” by the heat removal in the thermally conductive layer 63 so as to provide a relatively flat wavefront for the laser energy. However, the invention is not intended to be so limited as certain predictable radii of curvature may be desirable depending on a particular laser application. Accordingly, the tuner 113 may control the coolant flow/temperature between the flow ports 112 as a matter of design choice.

Even with the symmetric cooling from flow ports 112-1 and 112-2, optical distortions may still occur. For example, the bulging illustrated in FIG. 3 as well as the thermal lensing effect previously discussed may provide optical distortions and/or focusing effects. Asymmetric cooling can be used to provide mechanical stress on the gain medium to balance the distortions resulting from symmetric cooling.

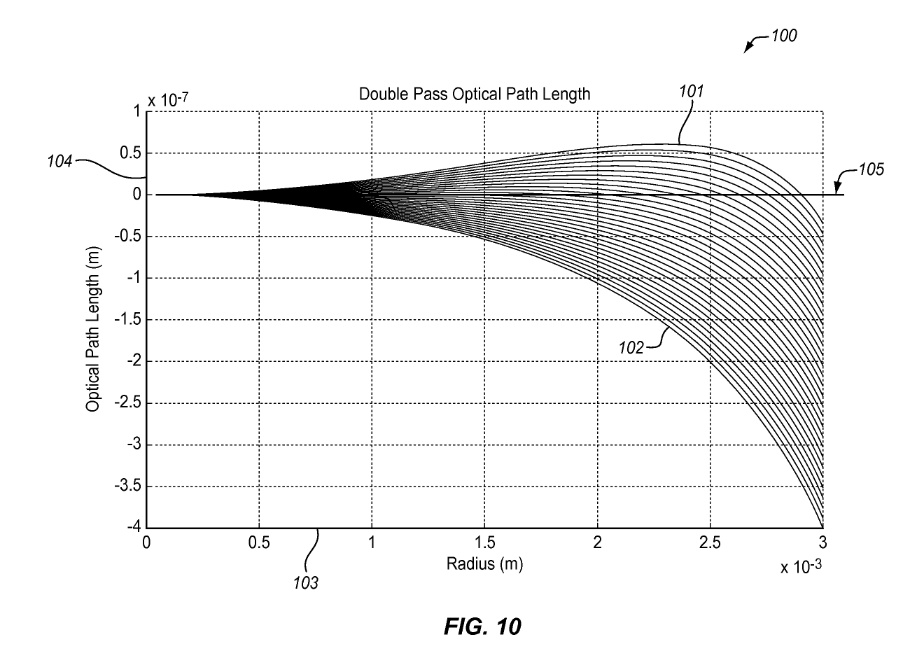

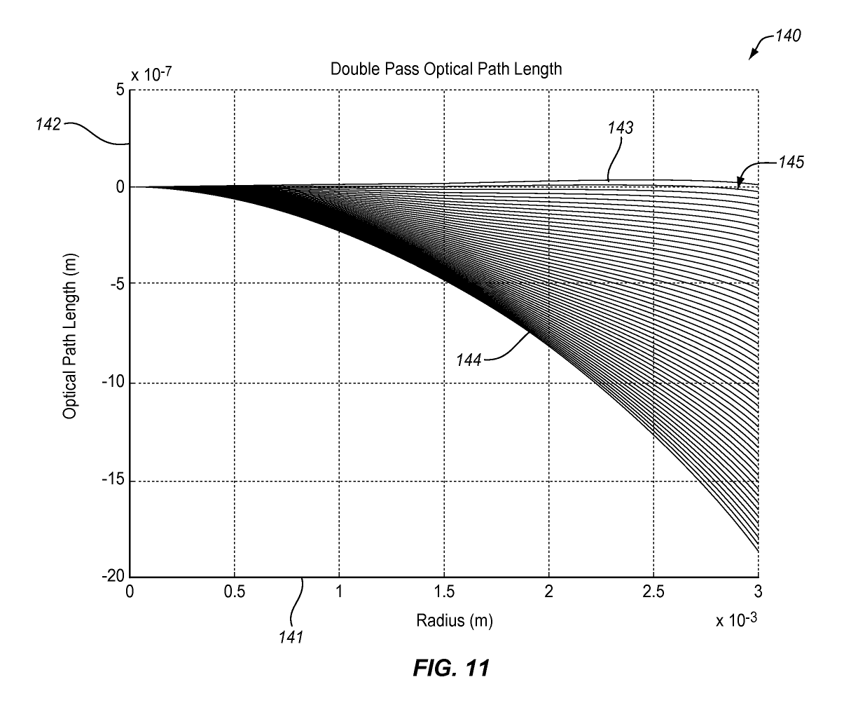

FIGS. 10 and 11 illustrate exemplary optical path lengths based on thermal tuning of a gain medium. Each of the graphs 100 and 140 provide information pertaining to the optical path length of a double pass (e.g., a round-trip) of the optical energy through the gain medium 60 with respect to the radius of curvature for a lens proximate to the gain medium. More specifically, FIG. 10 illustrates a graph 100 of thermal tuning using a single coolant proximate to the thermally conductive layer 63 disposed about the gain material 62 illustrated in FIG. 8. FIG. 11, on the other hand, illustrates a graph 140 of radially tuned cooling such as that shown and described in the laser gain medium configuration 110 of FIG. 9. In the graphs 100 and 140, the optical path length of the laser energy in meters is illustrated on the axes 104 and 142, respectively. The radial dimension in meters is shown on the axes 103 and 141, respectively. Each of the graphs 100 and 140 illustrate curves corresponding to the cooling temperature of a particular coolant flowing proximate to the thermally conductive materials disposed about the gain material 62. For example, in FIG. 10, the curve 102 corresponds to a warmer coolant temperature than the curve 101 when using a single coolant.

An optical path length curve with little radial dependence generally provides for a flat wavefront for the laser energy. Thus, if a flat wavefront is desired for the laser energy, the graph 100 may be used to locate a curve that is relatively tangential to the 0 m line 105 of the optical path length for a coolant temperature.

As mentioned, FIG. 11 illustrates a graph 140 showing similar curves that illustrate the radial dependence of the optical path length for different temperatures. In this embodiment, the curves 143 through 144 illustrate a range of temperatures (e.g., the curve 143 being about 350 K decreasing in temperature through the curve 144 being about 270 K) for a coolant flowing through the coolant port 112-1 with a coolant flowing through the flow port 112-2 at a constant temperature of about 293.15 K. In this embodiment, the constant temperature through the flow port 112-2 tends to cause focusing for a gain medium when the coolant through the flow port 112-1 is cooler and defocusing as the coolant through the flow port 112-1 is warmer. As can be seen from the graph 140, the radius of curvature for the lens is extended via the radial tuning of the coolants. For example, the curve 143 closely approximates the line 145 that corresponds to the 0 m of the optical path length.

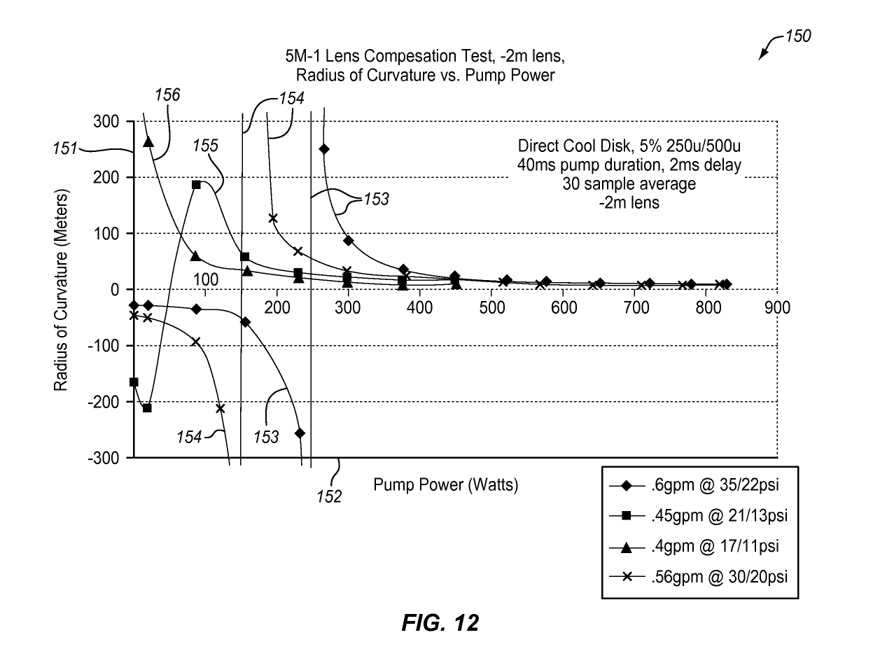

FIG. 12 is a graph 150 of the radius of curvature of the reflected light from a thin disk gain medium versus pump power of a laser with various coolant flow rates. More particularly, the graph 150 illustrates actual experimental results from cooling the gain medium 60 when the pump power is applied to the gain medium in 40 ms pulses with a 2 ms delay between pulses. As mentioned, an infinite radius of curvature for an optical energy wavefront is particularly advantageous in that a lens is not required to correct (e.g., focus) the laser energy exiting the gain medium.

The graph 150 illustrates this concept particularly with the plots 154 and 153. For example, the plot 155 illustrates the pump power applied to the gain medium 60 and the cooling applied to compensate for the thermal mechanical optical distortions caused by the pump power. In the plot 155, a coolant is flowed proximate to the thermally conductive materials 61 and 63 at a rate of about 0.45 gallons per minute (gpm) at a pressure of about 21/13 pounds per square inch (psi). In one embodiment, the system is compensated when the pump is set to approximately 50 Watts. Similarly, the plot 156 illustrates that a flow rate of about 0.4 gpm at 17/11 psi asymptotically approaches a flat wavefront when the pump optical energy power is essentially zero (i.e., not operational). However, in the plots 154 and 153, the flow rates of 0.56 gpm at 30/20 psi and 0.6 gpm at 35/22 psi yield relatively flat wave fronts at about 150 W and 250 W, respectively. That is, the radius of curvature of the optical wavefront for these two coolant flow rates at these pump powers in the plots 154 and 153 is relatively constant between 300 m and −300 m, yielding negligible thermal mechanical distortion.

Thus, as can be seen from the graph 150, the thermal mechanical distortions of the gain medium 60 may be controlled as a matter of coolant flow rate and pump power. This tunable coolant flow rate may assist the laser system designer by alleviating the complexity of the laser system design. For example, the laser energy may be configured with a wavefront of a particular radius of curvature that may be corrected with lenses already on hand. Alternatively or additionally, the laser system designer may design the laser system with a flat wavefront such that a lens is not required for correction.

In any case, the systems and methods described herein may provide the laser system designer with the ability to configure a laser system in many possible manners. For example, the laser designer may use a variety of mounting designs as virtually any thermal mechanical distortions in the gain medium may be corrected. Alternatively or additionally, the gain medium may be “pre-distorted” at some ambient condition so that at operating conditions of the disk curvature is within a range that is close to desired conditions. For example, FIG. 4 illustrates where the gain medium is fixed between two mounts where the gain medium is thermal mechanically distorted due to the radiation from the pump optical energy. It may be beneficial to preconfigure such distortion such that the direction of the “bend” is known and compensated to the original bend via the tunable cooling. In this regard, the preconfigured, albeit compensated, distortion could be further compensated by a lens as desired. As one can observe by the various configurations described herein, the invention is not intended to be limited to any particular configuration. Other preconfigured distortions may include varying the thickness of the gain medium such as that shown in described in FIG. 3. Also, the gain medium and thermally conductive layers, such as those shown and described in FIG. 6, may be configured in other ways. For example, certain design considerations may have the pump energy and/or the laser energy propagate through the gain medium as opposed to being reflected off the surface 64 in FIG. 6.

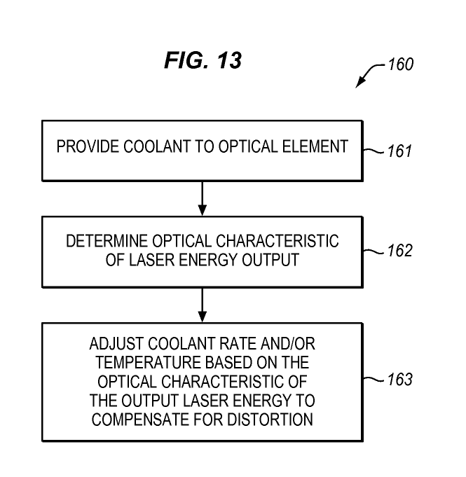

FIG. 13 is a flowchart of a process 160 for dynamically compensating optical distortion in a laser system. In this embodiment, a coolant is provided to an optical element in the process element 161. For example, a coolant such as water or liquid nitrogen may be provided at one or more flow rates proximate to the thermally conductive layers 61 and/or 63 shown and described in FIG. 1. In doing so, the coolant may tend to cool the conductive layers and thereby remove heat from the gain medium 62. In this regard, the process element 160 may call for the determination of an optical characteristic of the output in the process element 162. For example, a laser system may be configured to generate laser energy at a particular optical energy power output. Accordingly, it is generally desirable to determine the output power of the laser system prior to configuration. In any case, this output power of the laser energy (e.g., via the pump optical energy power) may heat the gain medium used to create the laser energy and thermal mechanically distort the optical characteristics of the gain medium. In this regard, the process element 163 compensates for this thermal mechanical distortion of the gain medium by adjusting the coolant flow rate and/or the temperature of the coolant based on the output optical characteristic (e.g., an optical wavefront, an optical path length, phase, etc. of the laser energy), in any one or more of the manners described herein.

While the invention has been illustrated and described in detail in the drawings and foregoing description, such illustration and description is to be considered as exemplary and not restrictive in character. For example, the tuner 13 described herein may be used to control flow rates of coolants proximate to the thermally conductive layers 61 and 63 disposed about the gain material 62. Alternatively or additionally, the tuner 13 may be used to control the temperatures of the coolants, either independently or in unison. Moreover, the tuner 13 may be used to control the cooling through electrical means such as Joule heating and Peltier cooling. Also, certain embodiments described hereinabove may be combinable with other described embodiments and/or arranged in other ways (e.g., process elements may be performed in other sequences). Accordingly, it should be understood that only the preferred embodiment and variants thereof have been shown and described and that all changes and modifications that come within the spirit of the invention are desired to be protected.

1. A method of controlling an optical wavefront of laser energy, including:
pumping a gain medium to generate laser energy; and
controllably adjusting a temperature of the gain medium to change an optical wavefront of the laser energy exiting the gain medium.

2. The method of claim 1, wherein controllably adjusting a temperature of the gain medium includes flowing a coolant proximate to the gain medium at a first flow rate to optically distort the gain medium and change the optical wavefront of the laser energy.

3. The method of claim 2, further including flowing the coolant through a second coolant port at a second flow rate proximate to the gain medium to further optically distort the gain medium.

4. The method of claim 1, wherein the gain medium is a Yb:YAG gain medium.

5. The method of claim 4, wherein the Yb:YAG gain medium is configured between first and second transmissive mediums each having a thermal conductivity of at least 3 W/(cm·K).

6. The method of claim 5, wherein the first and second transmissive mediums are configured from silicon carbide.

7. The method of claim 1, wherein controllably adjusting a temperature of the gain medium includes changing a flow rate of a coolant flowing proximate to a thermally conductive transmissive plate that is disposed proximate to the gain medium.

8. The method of claim 1, wherein controllably adjusting a temperature of the gain medium includes changing a temperature of a coolant flowing proximate to a thermally conductive transmissive plate that is disposed proximate to the gain medium.

9. The method of claim 1, wherein the gain medium is configured between a transmissive medium and a reflective medium.

10. The method of claim 1, further including detecting an optical characteristic of the laser energy and generating a control signal based on the detected optical characteristic to controllably adjust the temperature of the gain medium.

11. The method of claim 10, further including determining a focus of the laser energy, a phase distortion of the laser energy, or a combination thereof based on the detected optical characteristic to generate a control signal operable to direct the tuner.

12. A laser system, including:
a pump laser source operable to generate optical energy;
a gain medium operable to generate laser energy from the optical energy, wherein the gain medium includes a thermally conductive material; and
a tuner in thermal communication with the thermally conductive material, wherein the tuner is operable to controllably adjust a temperature of the gain medium via the thermally conductive material to optically distort the gain medium and change an optical wavefront of the laser energy.

13. The laser system of claim 12, wherein the gain medium includes Ytterbium.

14. The laser system of claim 12, wherein the thermally conductive material includes silicon carbide.

15. The laser system of claim 12, wherein the thermally conductive material has a thermal conductivity of at least 3 W/(cm·K).

16. The laser system of claim 12, wherein the tuner is operable to adjust a temperature of a coolant flowing proximate to the thermally conductive material to optically distort the gain medium.

17. The laser system of claim 16, wherein the coolant is water.

18. The laser system of claim 16, wherein the tuner includes first and second ports operable to flow the coolant proximate to the thermally conductive material.

19. The laser system of claim 12, wherein the tuner is operable to adjust a flow rate of a coolant flowing proximate to the thermally conductive material to optically distort the gain medium.

20. The laser system of claim 19, wherein the tuner is operable to flow the coolant through the first and second ports at first and second flow rates and wherein the first flow rate is different than the second flow rate.

21. The laser system of claim 12, further including a mount configured to retain the gain medium, wherein the mount is configured from copper tungstate.

22. The laser system of claim 12, further including a feedback system operable to detect an optical characteristic of the optical wavefront of the laser energy and direct the tuner to change a temperature, a flow rate, or a combination thereof, of a coolant flowing proximate to the gain medium to counter an optical distortion of the gain medium and change the optical characteristic of the optical wavefront.

23. The laser system of claim 22, wherein the thermally conductive material is configured as two plates disposed about a gain material, wherein each plate has a flow port operable to circulate the coolant proximate to the gain medium.

24. The laser system of claim 22, wherein the optical characteristic of the optical wavefront of the laser energy includes a beamspot size, a wavefront radial measurement, or a combination thereof to determine a focus of the laser energy, a phase distortion of the laser energy, or a combination thereof, wherein the determined focus, phase distortion, or combination is used to generate a control signal operable to direct the tuner.
